(19) United States
(12) Patent Application Publication
(10) Pub. No.: US 2008/0179493 A1
(43) Pub. Date: Jul. 31, 2008

(54) Image Reading Device

(75) Inventors: Yasuhiro Nagao, Kyoto (JP); Hiromi Ogata, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: Rohm Co., Ltd., Kyoto-shi (JP)

(21) Appl. No.: 11/667,347

(22) PCT Filed: Oct. 31, 2005
(86) PCT No.: PCT/JP05/19969

§ 371 Date: Sep. 20, 2007

(30) Foreign Application Priority Data
Nov. 8, 2004 (JP) 2004-323516

(51) Int. Cl. H01L 27/00

(52) U.S. Cl. 250/208.1

(57) ABSTRACT

An image reader (A) includes a case (1), a substrate (3) in the form of a strip, a plurality of light receiving elements (80) and a plurality of electrodes (10A, 10B). A dam member (20) projecting in the thickness direction of the substrate (3) is provided between the light receiving elements (80) and the electrodes (10A, 10B).

### TECHNICAL FIELD

The present invention relates to an image reader used for a facsimile machine or a scanner, for example.

### BACKGROUND ART

Generally, an image reader includes a case made of a synthetic resin and various parts mounted to the case (See Patent Document 1 below, for example). FIGS. 6 and 7 of the present application show an example of image reader as related art of the present invention. The illustrated image reader B includes a case 101, a transparent cover 102 mounted to an upper surface of the case, and a substrate 103 in the form of a strip mounted to the bottom of the case 101. In the case 101, a light guide 105 held by a reflector 106, and a lens array 107 are mounted. A light source 104 and sensor IC chips 108 aligned longitudinally of the substrate 103 are provided on the substrate 103. The light emitted from the light source 104 travels through the light guide 105 to impinge on a document P via the transparent cover 102 and is reflected thereon. The reflected light travels through the lens array 107 and converges on a plurality of light receiving elements (not shown) incorporated in the sensor IC chips 108. Each of the light receiving elements outputs an image signal of the output level corresponding to the amount of received light. By processing these signals, a read image is obtained.

In the image reader B, the bottom of the case 1 is formed with a downwardly projecting peripheral wall 101a. The substrate 103 is fitted into a recess 101b defined inward of the peripheral wall 101a and is thereby mounted to the case 101. The peripheral wall 101a functions to prevent external light or foreign matters from entering the case 101 through a gap between the case 101 and the substrate 103. A connector 109 is provided at one of longitudinally opposite ends of the substrate 103. The connector 109 is used for connecting the substrate 103 to an external device and so provided as to partially project out from a longitudinal edge of the substrate 103. The peripheral wall 101a of the case 101 is formed with a cutout 101c at a portion corresponding to the connector 109. Therefore, in mounting the substrate 103 to the case 101, contact between the connector 109 and the peripheral wall 101a is avoided.

For the purpose of reliably preventing the contact with the connector 109 or making it possible to use connectors of different sizes and so on, the cutout 101c is generally made larger than the contact area with the connector. Therefore, when the substrate 103 is mounted to the case 101, a relatively large gap c1 is defined between the cutout 101c and the connector 109, so that external light or foreign matters may enter the case 101 through the gap c1. To prevent this, as shown in FIG. 7, the case 1 is formed with a downwardly projecting partition wall 101d at a position which is closer to the light receiving elements relative to the cutout 101c and which corresponds to the cutout 101c.

However, the image reader B has a drawback that entering of foreign matters cannot be sufficiently prevented. Specifically, when the substrate 103 is mounted to the case 101, a small gap may be defined between the end of the partition wall 101d and the surface of the substrate 103 due to the tolerance of dimensions of the parts. Further, a gap c2 may be intentionally provided to prevent contact between the partition wall 101d and parts mounted on the substrate 103. In this instance, foreign matters may enter the region adjacent to the light receiving elements in the case 101 through the gap c2 and adhere to the light receiving elements. In this instance, the light receiving elements cannot detect light properly, whereby the quality of the read image is deteriorated.

Image signals are liable to be influenced by electric noise, and inclusion of noise in image signals deteriorates the quality of the read image. To prevent this, for example, an electrode as a noise shield is provided in the case 101. Specifically, for example, as shown in FIG. 8, electrodes 110A and 110B are formed on the substrate 103 and the lower end surface of the partition wall 101d of the case 101 by applying silver paste having excellent conductivity. The electrode 110A is connected to a wiring (not shown) provided on the substrate 103, whereas the electrode 110B is connected to ground via a solder bump 111 formed on the electrode 110A. With this structure, the case 101 is not charged excessively, and inclusion of noise into image signals can be prevented.

However, in the structure including the electrodes 110A and 110B, silver particles contained in the electrodes 110A and 110B may scatter. When the scattered silver particles adhere to the light receiving elements, the light receiving elements cannot detect light properly, which deteriorates the quality of the read image.

Patent Document 1: JP-A-2004-193773

### DISCLOSURE OF THE INVENTION

An object of the present invention, which is conceived under the above-described circumstances, is to provide an image reader which is capable of preventing adhesion of foreign matters to the light receiving elements and obtaining a proper read image.

To solve the above-described problems, the present invention takes the following technical measures.

According to the present invention, there is provided an image reader comprising a case, a substrate in the form of a strip mounted to the case, a plurality of light receiving elements for image reading accommodated in the case and provided on the substrate in an array extending in the longitudinal direction of the substrate, and an electrode formed at least one of the case and the substrate by applying conductive paste. The image reader further comprises a dam member which is provided on the substrate between the light receiving elements and the electrode, and which projects in the thickness direction of the substrate.

With this structure, it is possible to prevent foreign matters from adhering to the light receiving elements. Specifically, since the dam member projecting in the thickness direction of the substrate is provided at an appropriate portion between the light receiving elements and the cutout, the dam member blocks and keeps the component particles of the electrode on the electrode side even when the component particles are scattered. Therefore, the component particles of the electrode are properly prevented from adhering to the light receiving elements on the substrate. Thus, according to the present invention, a properly-read image can be obtained.

In a preferred embodiment of the present invention, the image reader further comprises a connector provided at the substrate to connect the substrate to an external device. The case is formed with a cutout for avoiding contact with the connector, and the dam member is provided between the light receiving elements and the cutout.

With this structure, even when a gap is defined between the cutout and the connector and foreign matters enter the case through the gap, the dam member blocks and keeps the foreign matters entered the case on the cutout side, because the dam member is provided at an appropriate portion between the light receiving elements and the cutout. Therefore, foreign matters are properly prevented from adhering to the light receiving elements, so that a proper read image can be obtained.

In a preferred embodiment of the present invention, the dam member includes a strip portion extending in a substantially same direction as the alignment direction of the light receiving elements.

With this structure, foreign matters or the component particles of the electrode can be blocked efficiently, so that the width of the strip portion can be made small. Therefore, it is possible to properly prevent foreign matters or the component particles of the electrode from adhering to the light receiving elements while making the area for providing the dam member small.

In a preferred embodiment of the present invention, the dam member is made of synthetic resin. Further, in the present invention, it is preferable that the dam member is made of silicone resin.

With this structure, the dam member provided on the substrate is not electrically connected to a conductive portion on the substrate and hence does not adversely affect the operation of the image reader. Further, when the dam member is made of silicone resin, the dam member itself is viscous. Therefore, foreign matters adhered to the dam member do not scatter again, which is advantageous for preventing foreign matters from adhering to the light receiving elements.

Other features and advantages of the present invention will become clearer from the description of embodiments of the present invention given below.

### BRIEF DESCRIPTION OF THE DRAWINGS

FIG. 1 is an exploded perspective view showing an example of image reader according to the present invention.

FIG. 2 is a sectional view taken along lines II-II in FIG. 1.

FIG. 3 is a sectional view taken along lines III-III in FIG. 1.

FIG. 4 is a sectional view taken along lines IV-IV in FIG. 3.

FIG. 5 is a sectional view showing another example of image reader according to the present invention.

FIG. 6 is an exploded perspective view showing an example of image reader as related art of the present invention.

FIG. 7 is a sectional view taken along lines VII-VII in FIG. 6.

FIG. 8 is a sectional view showing another example of image reader as related art of the present invention.

### BEST MODE FOR CARRYING OUT THE INVENTION

Preferred embodiments of the present invention will be described below with reference to the accompanying drawings.

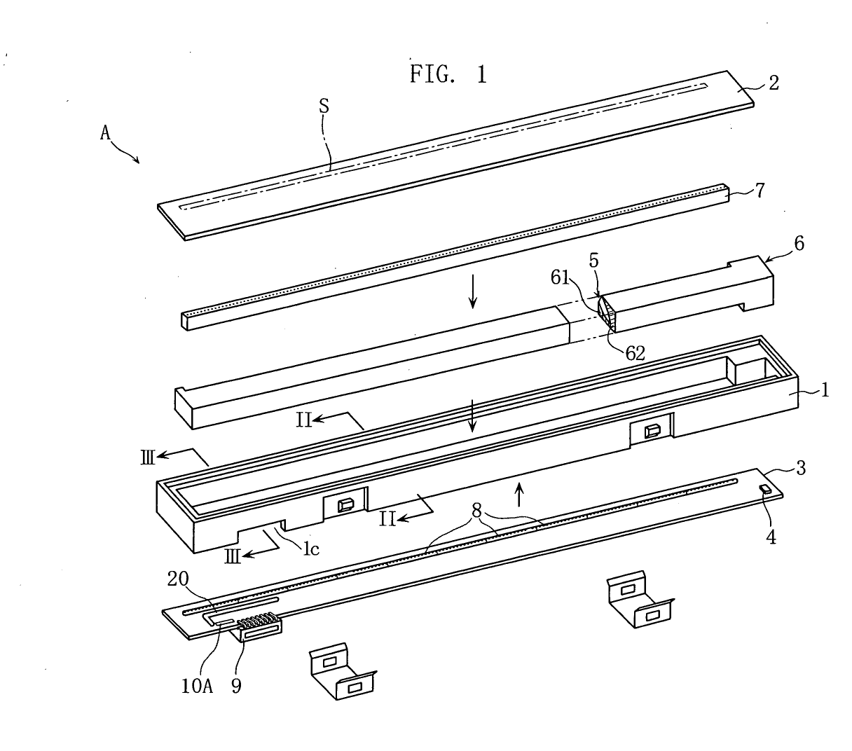

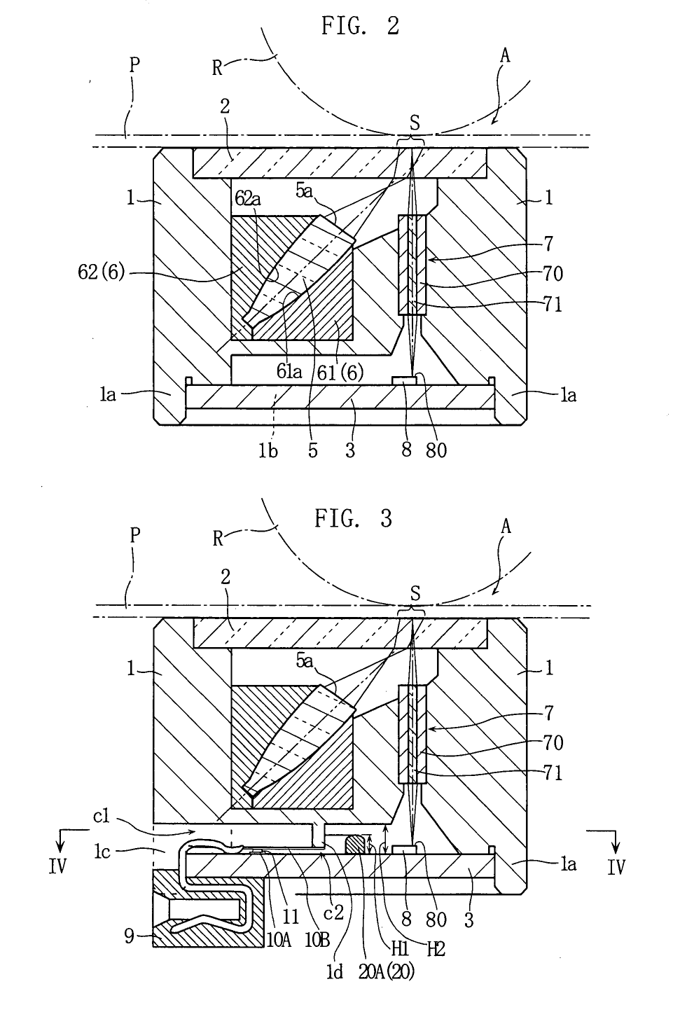

FIGS. 1-4 show an example of image reader according to the present invention. For instance, the image reader A of this embodiment is used as a structural part of a scanner in which a document is transferred by e.g. a platen roller R. The imager reader A includes a case 1, a transparent cover 2, a substrate 3, a light source 4, a light guide 5, a reflector 6, a lens array 7, a plurality of sensor IC chips 8, a connector 9, electrodes 10A, 10B and a dam member 20.

The case 1 is made of synthetic resin containing carbon fiber, for example, and in the form of a box elongated in the primary scanning direction. For instance, the transparent cover 2 comprises a glass plate or a synthetic resin plate which is in the form of an elongated rectangle in plan view. The transparent cover 2 is mounted to an upper surface of the case 1 so as to close an upper opening of the case 1. The lens array 7 includes a holder 70 made of synthetic resin and elongated in the primary scanning direction, and a plurality of lenses 71 arranged in a row and held by the holder. For instance, each of the lenses 71 may comprise a rod lens. The lens array 7 is so mounted to the case 1 as to face the reverse surface of the transparent cover 2.

The light source 4 includes e.g. three kinds of LED chips for emitting red light, green light and blue light, respectively, which are collectively resin-packaged. The light source 4 is mounted on the substrate 3 at one of longitudinally opposite ends of the substrate.

The light guide 5 efficiently guides the light emitted from the light source 4 to the entire area of a document read region S of the transparent cover 2. The light guide is in the form of a block elongated in the longitudinal direction of the case 1. The light guide 5 may be made of a transparent acrylic resin such as PMMA or other materials having excellent light transmittance. All the surfaces of the light guide 5 are made as a mirror surface. The lower surface of the light guide 5 is formed with a plurality of recesses (not shown) spaced from each other by a predetermined distance in the longitudinal direction. When the light traveling through the liquid guide 5 impinges on the recesses, the light is scattered in various directions. Thereafter, the light is emitted from a light emitting surface 5a toward the image read region S.

The reflector 6 comprises a first member 61 and a second member 62, both of which have an overall length corresponding to the overall length of the light guide 5. The first member 61 and the second member 62 of the reflector hold the light guide 5 therebetween. The first and the second members 61 and 62 serve to prevent the light emitted from the light source 4 from unduly leaking to the outside of the light guide 5. For this purpose, the reflector 6 is made of e.g. white resin to have a high-reflectivity. The first and the second members 61 and 62 have reflective surfaces 61a and 62a, respectively, which are designed to fit to the light guide 5. The light emitted from the light source 4 travels while repeating total reflection at the surfaces of the light guide 5 or reflection at the reflective surfaces 61a, 62a and is then emitted from the light emitting surface 5a of the light guide 5 toward the document read region S. The reflector 6 is mounted to the case 1 while integrally holding the light guide 5.

Each of the sensor IC chips 8 comprises a semiconductor chip including an integrated circuit provided with a plurality of light receiving elements 80. The sensor IC chips are mounted on the substrate 3 to be aligned in the primary scanning direction (longitudinal direction of the substrate 3) in contact with each other. The sensor IC chips 8 can receive the light passed through the lens array 7 at the light receiving elements 80 when the substrate 3 is mounted to the bottom of the case 1. Each of the light receiving elements 80 has a photoelectric conversion function. Thus, when the light receiving element receives light at a predetermined light receiving surface, the light receiving element outputs a signal (image signal) of the level corresponding to the amount of received light.

The substrate 3 is in the form of a strip made of ceramic material, for example. The connector 9 for connecting the substrate 3 to an appropriate external device is provided at one of longitudinally opposite ends of the substrate. On the substrate 3, a wiring (not shown) for electrically connecting the connector 9 to the light source 4 and the sensor IC chips 8 are provided. The power supply to the light source 4 and signal input and output with respect to the sensor IC chips 8 are performed through the wiring and the connector 9.

The substrate 3 is mounted to the bottom of the case 1 so as to close a bottom opening of the case 1. Specifically, the bottom of the case 1 is formed with a downwardly projecting peripheral wall 1a, and the substrate 3 is mounted to the case 1 by fitting into a recess 1b defined inwardly of the peripheral wall 1a. The peripheral wall 1a prevents external light or foreign matters such as dust from entering the case 1 through a gap between the case 1 and the substrate 3. The peripheral wall 1a is formed with a cutout 1c at a portion corresponding to the connector 9. Therefore, in mounting the substrate 3 to the case 1, the connector 9 is prevented from coming into contact with the peripheral wall 1a. The cutout 1c has a size larger than the contact area with the connector 9. Therefore, when the substrate 3 is mounted to the case 1, a relatively large gap c1 is defined between the cutout 1c and the connector 9. The case 1 is integrally formed with a downwardly projecting partition wall 1d at a position which is closer to the light receiving elements 80 relative to the cutout 1c and which corresponds to the cutout 1c.

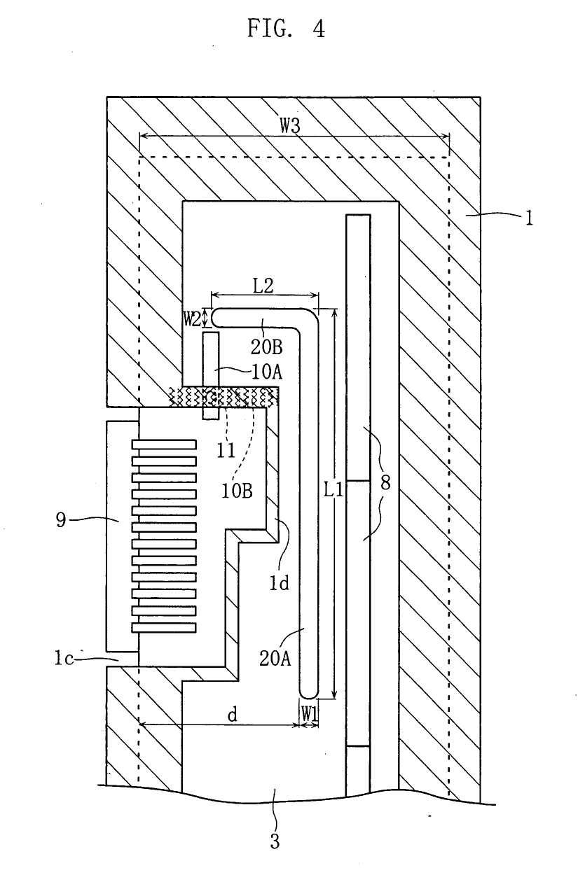

As shown in FIGS. 3 and 4, the electrodes 10A and 10B are formed, respectively, on the wiring on the substrate 3 and on the lower end surface (the portion with crossed pattern in FIG. 4) of the partition wall 1d so as to face each other at least partially. The electrodes 10A and 10B are formed by applying silver paste, for example, and positioned adjacent to the connector 9. The silver paste may be formed by mixing silver particles with resin binder and further with a viscous medium containing an organic resin in a solvent. On the electrode 10A, a solder bump 11 is provided at a portion facing the electrode 10B. The electrode 10A is connected to the wiring, whereas the electrode 10B is connected to ground via the solder bump 11 and the electrode 10A. With this structure, the case 1 is not charged excessively, so that inclusion of noise in the image signals can be prevented.

The dam member 20 projecting in the thickness direction of the substrate 3 is provided on the substrate 3 via e.g. an adhesive. The dam member 20 is made of e.g. silicone resin and comprises a first strip portion 20A extending in the primary scanning direction (longitudinal direction of the substrate 3) and a second strip portion 20B extending in the secondary scanning direction (width direction of the substrate 3) which are formed integrally. The dam member 20 is so provided as to correspond to the position of the cutout 1c and the electrodes 10A, 10B. To give an example of dimensions of the substrate 3 and the nearby portions in this embodiment, the length in the longitudinal direction of the substrate 3 is about 230 mm, the width W3 of the substrate 3 is about 14 mm, the distance H2 from the surface of the substrate 3 to the inner bottom surface of the case 1 is about 1.2 mm, and the distance d from the cutout 1c to the first strip portion 20A is about 7 mm. When the above-described dimensions are defined, the dimensions of the dam member 20 are as follows. That is, the height H1 of the dam member 20 is about 0.55 to 1.1 mm, the width W1, W2 of the first and the second strip portions 20A and 20B is about 1 to 1.5 mm, the length L1 of the first strip portion 20A is about 20 to 22 mm, the length L2 of the second strip portion 20B is about 4 to 5 mm.

The operation of the image reader A will be described below.

First, when the light source 4 is turned on, the light is guided to the light guide 5. The light repeats total reflection at various surface portions of the light guide 5 or reflection at the reflective surfaces 61a and 62a of the reflector 6 and is then emitted from the light emitting surface 5a of the light guide 5 toward the document read region S. The light reflected at the surface of the document P on the image read region S passes through the lenses 71 of the lens array 7 and is received by the light receiving elements 80 incorporated in the sensor IC chips 8. In this way, the image of the document P is formed on the light receiving elements 80. The image signals outputted from the light receiving elements 80 are processed, whereby the read image is obtained.

At the electrodes 10A and 10B, deterioration of adhesion may occur due to e.g. the volatilization of the solvent contained in the silver paste which is the material of the electrodes, and silver particles may scatter from the surfaces of the electrodes 10A and 10B. However, the dam member 20 is provided between the light receiving elements 80 and the electrodes 10A, 10B so as to positionally correspond to the electrodes 10A, 10B. Therefore, even when silver particles are scattered, the dam member 20 blocks and keeps the silver particles on the electrode 10A, 10B side. Therefore, the silver particles are prevented from adhering to the light receiving elements 80, so that a proper read image can be obtained.

Moreover, foreign matters may enter the case 1 through the gap c1 and further through a gap c2 defined under the partition wall 1d. Even in such a case, since the dam member 20 is provided between the light receiving elements 80 and the cutout 1c so as to correspond to the position of the cutout 1c, the foreign matters entered the case 1 is blocked and kept on the cutout 1c side by the dam member 20. Therefore, foreign matters are properly prevented from adhering to the light receiving elements 80.

In this embodiment, the dam member 20 includes the first strip portion 20A extending in the primary scanning direction. That is, the first strip portion 20A extends generally in the same direction as the direction in which the light receiving members 80 are aligned. Conceivably, silver particles and foreign matters scatter from the electrodes 10A, 10B or the gap c1 uniformly to the adjacent portions. Therefore, the first strip portion 20A extending in the direction in which the light receiving elements 80 are aligned can efficiently block silver particles and foreign matters. Therefore, the width w1 of the first strip portion 20A can be made small. Thus, it is possible to properly prevent silver particles and foreign matters from adhering to the light receiving elements 80 while making the area for providing the dam member 20 small. Further, by making the width of the first strip portion 20A small, contact with other parts such as a capacitor or a jumper (not shown) appropriately provided on the substrate 3 can be avoided easily, which is advantageous. In this embodiment, the electrodes 10A, 10B and the connector 9 are provided at an end of the substrate 3. Therefore, by providing the second strip portion 20B which is integral with the first strip portion 20A and which extends generally perpendicularly to the first strip portion, silver particles or foreign matters are properly prevented from reaching the above-mentioned end of the substrate 3 beyond the second strip portion 20B.

In this embodiment, the dam member 20 is made of silicone resin. When the dam member 20 is made of an insulating material such as silicone resin, the dam member is not electrically connected to a conductive portion on the substrate 3 and hence does not adversely affect the operation of the image reader A. Further, since silicone resin is viscous, foreign matters adhered to the dam member 20 do not scatter again, which is advantageous for preventing foreign matters from adhering to the light receiving elements. Of course, the dam member in the present invention is not limited to one made of silicone resin but may be made of other insulating synthetic resin, for example.

The image reader according to the present invention is not limited to the foregoing embodiment.

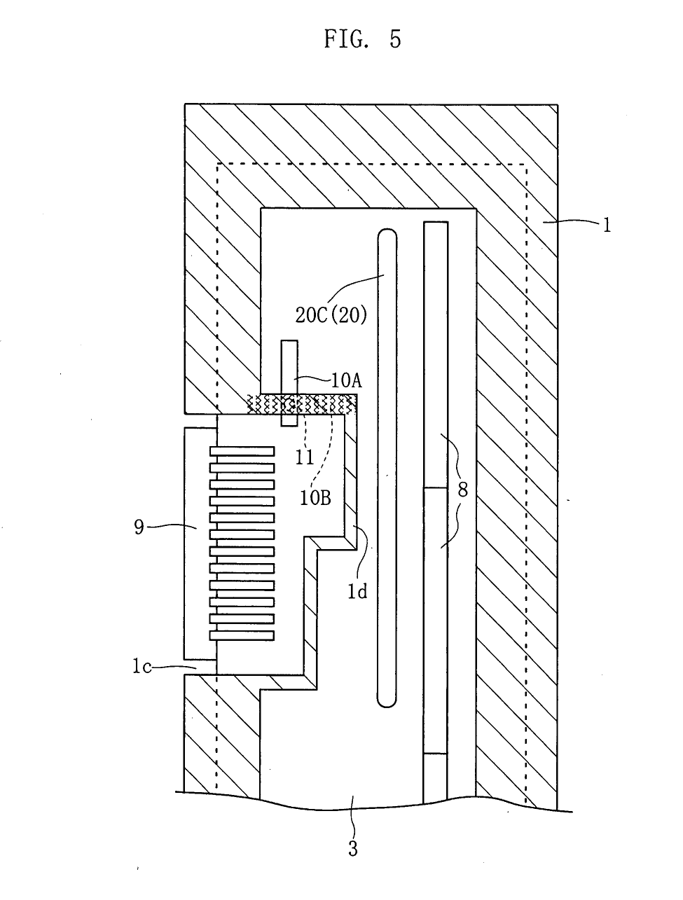

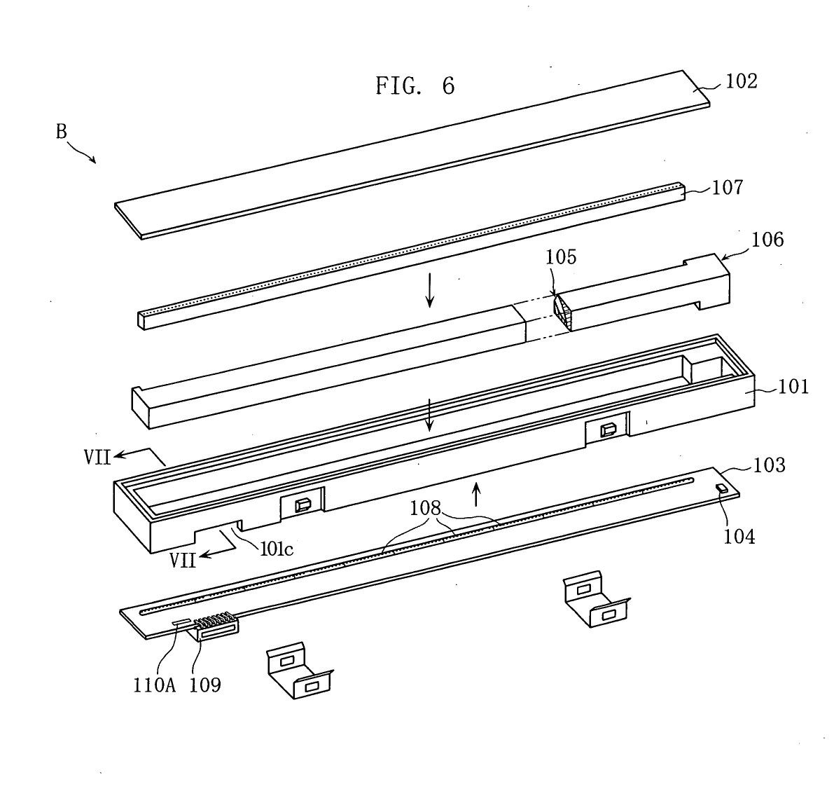

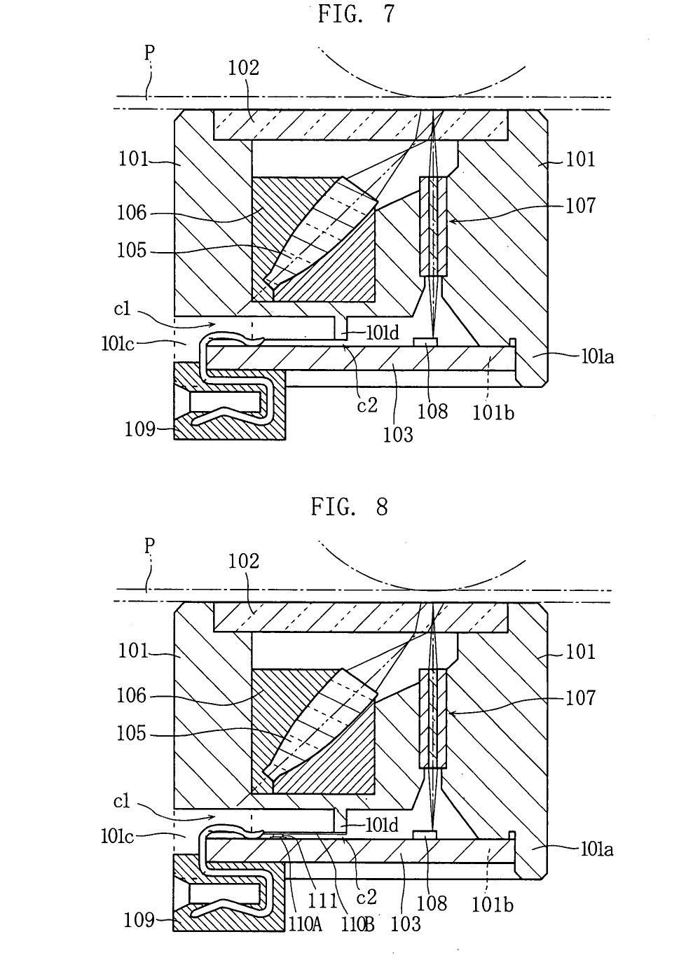

Although the dam member 20 is made up of the first strip portion 20A and the second strip portion 20B in the foregoing embodiment, the present invention is not limited to this structure. For instance, as shown in FIG. 5, the dam member 20 may comprise only a strip portion 20C extending in the direction in which the light receiving elements 80 are aligned. The shape of the dam member 20 comprising the strip portion 20C only is simple, which is advantageous.

The dimensions of the dam member 20 and other portions are not limited to those exemplarily described in the foregoing embodiment. Conceivably, silver particles and foreign matters scatter from the electrodes 10A, 10B or the gap c1 uniformly to the adjacent portions. Therefore, when it is possible to arrange the dam member close to the electrodes or the gap, the length of the strip portions of the dam member can be reduced correspondingly. The height H1 of the dam member in the height range described in the foregoing embodiment is preferable when the distance H2 from the surface of the substrate 3 to the inner bottom surface of the case 1 is about 1.2 mm and sufficient height for blocking silver particles or foreign matters even when the silver particles or foreign matters rise slightly from the surface of the substrate 3. Accordingly, the height H1 can be set appropriately in accordance with the distance H2. Although a gap is defined between the dam member 20 and the inner bottom surface of the case 1 in the foregoing embodiment, the gap can be eliminated so that the dam member comes into close contact with the inner bottom surface of the case.

In the foregoing embodiment, the electrodes 10A and 10B are arranged adjacent to the connector 9. However, the present invention is applicable to a structure in which the electrodes and the connector are spaced from each other in the longitudinal direction of the substrate. In such a structure, the dam member is separately provided at respective positions corresponding to the electrodes and the connector.

Although the image reader A in the foregoing embodiment is an example to be used as mounted in a scanner in which a document is transferred by a platen roller, the present invention is not limited thereto. The image reader of the present invention can be used widely for various devices in which image reading is to be performed, such as a so-called flatbed scanner or handy scanner.

1. An image reader comprising:
a case;
a substrate in a form of a strip mounted to the case;
a plurality of light receiving elements for image reading accommodated in the case, the light receiving elements being provided on the substrate in an array extending in a longitudinal direction of the substrate; and
an electrode formed at least one of the case and the substrate by applying conductive paste;
wherein the substrate is provided with a dam member between the light receiving elements and the electrode, the dam member projecting in a thickness direction of the substrate.

2. The image reader according to claim 1, further comprising a connector provided at the substrate for connecting the substrate to an external device, wherein the case is formed with a cutout for avoiding contact with the connector, and wherein the dam member is provided between the light receiving elements and the cutout.

3. The image reader according to claim 1, wherein the dam member includes a strip portion extending in a same direction as the alignment direction of the light receiving elements.

4. The image reader according to claim 1, wherein the dam member is made of synthetic resin.

5. The image reader according to claim 4, wherein the dam member is made of silicone resin.
